(19) United States
(12) Patent Application Publication
(10) Pub. No.: US 2013/0125961 A1
(43) Pub. Date: May 23, 2013

(54) OPTICAL PASSIVATION FILM, METHOD FOR MANUFACTURING THE SAME, AND SOLAR CELL

(71) Applicants: Wen-Ching Sun, Hsinchu City (TW); Sheng-Min Yu, Taoyuan County (TW); Tai-Jui Wang, Kaohsiung City (TW); Chia-Liang Sun, Hsinchu City (TW); Tzer-Shen Lin, Hsinchu City (TW)

(72) Inventors: Wen-Ching Sun, Hsinchu City (TW); Sheng-Min Yu, Taoyuan County (TW); Tai-Jui Wang, Kaohsiung City (TW); Chia-Liang Sun, Hsinchu City (TW); Tzer-Shen Lin, Hsinchu City (TW)

(73) Assignee: INDUSTRIAL TECHNOLOGY RESEARCH INSTITUTE, Hsinchu (TW)

(21) Appl. No.: 13/459,250

(22) Filed: Apr. 30, 2012

(30) Foreign Application Priority Data
Nov. 18, 2011 (TW) 100142252

(51) Int. Cl. H01L 31/02; C09D 1/00; B05D 5/06

(52) U.S. Cl. 136/252; 427/162; 106/286.2

(57) ABSTRACT

An optical passivation film includes Tiᵢ₋ₓAlₓO_{y}:Z, where Z represents a halogen, x is from 0.05 to 0.95, and y is greater than 0. A method for manufacturing the optical passivation film includes preparing a spray solution including an aluminium oxide precursor, a titanium oxide precursor, a halogen solution and a solvent. A substrate is disposed on a heating device to heat the substrate. The spray solution is sprayed on the substrate to form the optical passivation film. A solar cell having the optical passivation film is also provided.

### CROSS-REFERENCE TO RELATED APPLICATION

This application claims the priority benefit of Taiwan application serial no. 100142252, filed on Nov. 18, 2011. The entirety of the above-mentioned patent application is hereby incorporated by reference herein and made a part of this specification.

### BACKGROUND

1. Technical Field

The disclosure relates to an optical passivation film, a method for manufacturing the same, and a solar cell having the optical passivation film.

2. Related Art

Solar power, as an inexhaustible and pollution-free energy, is always a focus of interest in solving the problem of pollution and shortage encountered by the fossil energy. A solar cell can directly convert the solar power into electric energy, and thus becomes a research subject at present.

In the solar cell, an anti-reflection coating plays a role. For the anti-reflection coating, in addition to an appropriate reflective index, after the surface thereof is passivated, a carrier lifetime and a film charge amount are also factors affecting the efficiency of the solar cell. In a conventional solar cell, titanium oxide, aluminium oxide, or silicon nitride is used as an anti-reflection coating. However, using titanium oxide as the anti-reflection coating has a disadvantage that the incident light cannot be efficiently used due to an over-large reflective index, and a poor passivation effect also causes frequent occurrence of electron recombination, so that the cell efficiency is lowered. Furthermore, although aluminium oxide used as the anti-reflection coating has a better passivation effect than that of titanium oxide, an excessively low reflective index causes the incident light to be largely reflected, so a purpose of anti-reflection cannot be achieved.

### SUMMARY

An optical passivation film is introduced herein, which includes Ti₁₋ₓAlₓO_{y}:Z, where Z represents a halogen, x is from 0.05 to 0.95, and y is greater than 0.

A method for manufacturing the optical passivation film is further introduced herein, which includes preparing a spray solution including an aluminium oxide precursor, a titanium oxide precursor, a halogen solution and a solvent. A substrate is disposed on a heating device to heat the substrate. The spray solution is sprayed on the substrate to form an optical passivation film, in which the optical passivation film includes Ti₁₋ₓAlₓO_{y}:Z, where Z represents a halogen, x is from 0.05 to 0.95, and y is greater than 0.

A solar cell is further introduced herein, which includes a semiconductor substrate, an optical passivation film, a first electrode, and a second electrode. The optical passivation film is disposed on the semiconductor substrate. The optical passivation film includes Ti₁₋ₓAlₓO_{y}:Z, where Z represents a halogen, x is from 0.05 to 0.95, and y is greater than 0. The first electrode and the second electrode are disposed respectively on two opposite surfaces of the semiconductor substrate.

Several exemplary embodiments accompanied with figures are described in detail below to further describe the disclosure in details.

### BRIEF DESCRIPTION OF THE DRAWINGS

The accompanying drawings are included to provide a further understanding, and are incorporated in and constitute a part of this specification. The drawings illustrate exemplary embodiments and, together with the description, serve to explain the principles of the disclosure.

FIG. 1 is a schematic view of a solar cell according to an embodiment of the disclosure;

FIG. 2 is a schematic flow chart of manufacturing an optical passivation film according to an embodiment of the disclosure;

FIGS. 3 and 4 are schematic views of a method for manufacturing an optical passivation film according to an embodiment of the disclosure;

FIG. 5 is a graph showing a relation between a composition and a reflective index, and a carrier lifetime of an optical passivation film according to an embodiment of the disclosure; and

FIG. 6 is a graph showing a relation between a bias and a standard capacitance value of an optical passivation film according to an embodiment of the disclosure.

### DETAILED DESCRIPTION OF DISCLOSED EMBODIMENTS

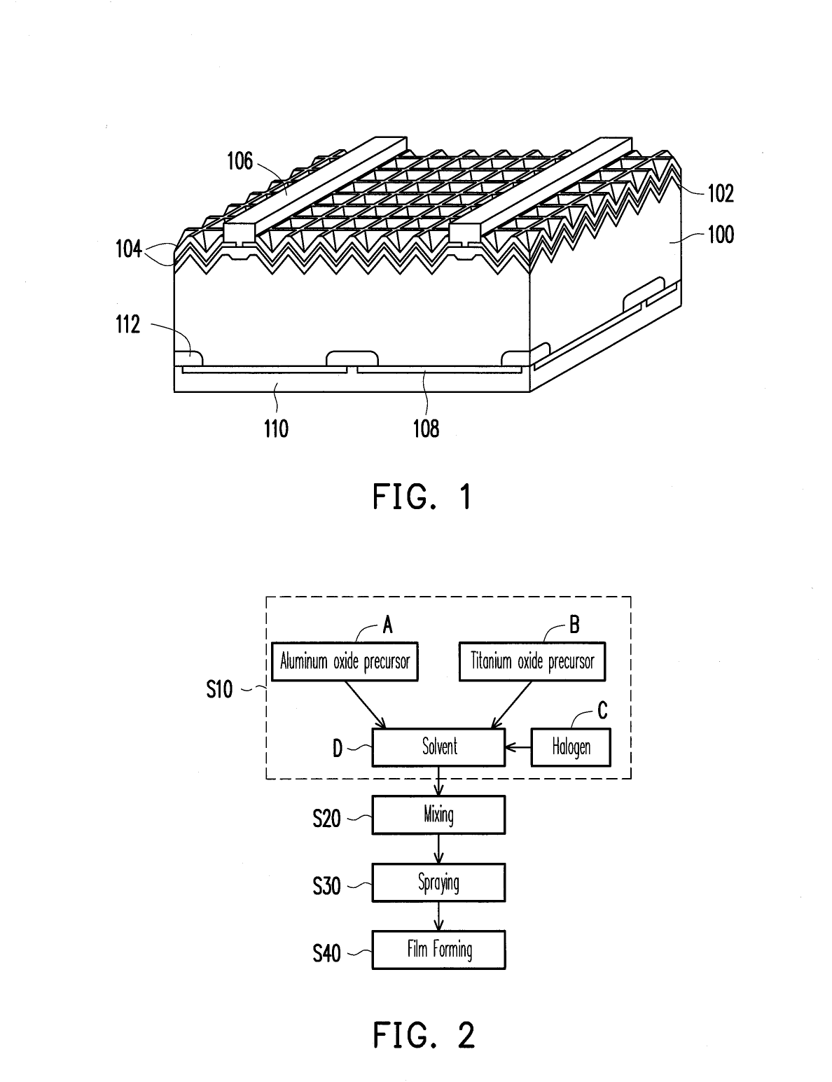

FIG. 1 is a schematic view of a solar cell according to an embodiment of the disclosure. Referring to FIG. 1, the solar cell provided in this embodiment includes a semiconductor substrate 100, an optical passivation film 104, a first electrode 106, and a second electrode 110.

According to this embodiment, the semiconductor substrate 100 is a semiconductor material doped with a p-type dopant. The semiconductor material includes single-crystal silicon or polycrystal silicon. The p-type dopant doped in the semiconductor material may be selected from the group consisting of the elements of Group III in the periodic table of elements, for example, boron (B), aluminium (Al), gallium (Ga), and indium (In).

According to this embodiment, a doped layer 102 is further formed in one surface of the semiconductor substrate 100. The doped layer 102, for example, may be an n-type doped layer, so as to form a p-n junction between the semiconductor substrate 100 and the doped layer 102. Here, the n-type dopant may be selected from the group consisting of the elements of Group V in the periodic table of elements, such as phosphorus (P), arsenic (As), or stibium (Sb).

The optical passivation film 104 is disposed on the doped layer 102 of the semiconductor substrate 100. The optical passivation film 104 may be a single-layer film or a multi-layer film. Especially, the optical passivation film 104 includes Ti₁₋ₓAlₓO_{y}:Z, where Z represents a halogen, x is from 0.05 to 0.95, and y is greater than 0. In other words, the optical passivation film 104 is formed by blending titanium, aluminium, and halogen atoms. The composition thereof is totally different from that of a conventional anti-reflection coating (titanium oxide, aluminium oxide, or silicon nitride).

Based on the aforesaid, in the optical passivation film (Ti₁₋ₓAlₓO_{y}:Z) 104, Z (halogen) may be fluorine, chlorine, bromine, or iodine. In addition, the halogen is present in the optical passivation film at an amount of at least 10¹⁸ atoms/cm³. Exemplarily, the halogen is present in the optical passivation film at an amount of 10¹⁸-10²¹ atoms/cm³.

The first electrode 106 and the second electrode 110 are disposed respectively on two opposite surfaces of the semiconductor substrate 100. The first electrode 106 may be of a finger-like electrode structure or other suitable electrode structures. The second electrode 110 is a back-contact electrode.

Generally, a dielectric layer 108 and a doped area 112 may be further disposed between the second electrode 110 and the semiconductor substrate 100. The dielectric layer 108 is, for example, silicon oxide, silicon nitride, or other dielectric materials. The doped area 112 is, for example, a p-type doped area. The dopant in the p-type doped area may be selected from the group consisting of the elements of Group III in the periodic table of elements, for example, boron (B), aluminium (Al), gallium (Ga), and indium (In).

In the solar cell provided in this embodiment, the optical passivation film (Ti₁₋ₓAlₓO_{y}:Z) 104 has a light capturing performance and an optical passivation effect, so that the use of the optical passivation film (Ti₁₋ₓAlₓO_{y}:Z) as the anti-reflection coating of the solar cell can effectively improve the efficiency of the solar cell.

The optical passivation film (Ti₁₋ₓAlₓO_{y}:Z) may be manufactured as described in the two implementations below.

### Embodiment 1

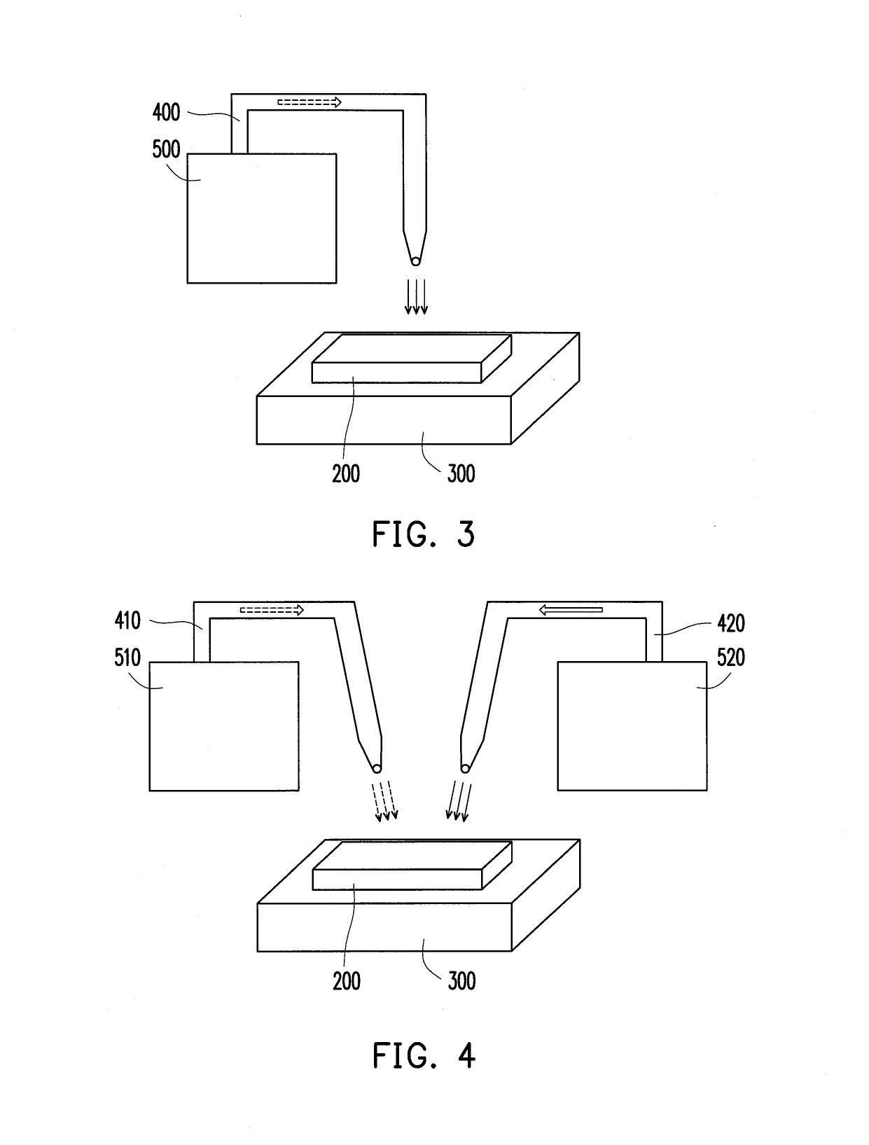

FIG. 2 is a schematic flow chart of manufacturing an optical passivation film according to an embodiment of the disclosure. FIG. 3 is a schematic view of a method for manufacturing an optical passivation film according to an embodiment of the disclosure. Referring to FIGS. 2 and 3, Step S10 is performed first, to prepare a spray solution. The spray solution includes an aluminium oxide precursor A, a titanium oxide precursor B, a halogen solution C and a solvent D.

The aluminium oxide precursor A includes an aluminium alkoxide (Al[OCH(CH₃)₂)]₃), aluminium chloride (AlCl₃), or aluminium nitrate. The titanium oxide precursor B includes a titanium alkoxide (Ti[OCH(CH₃)₂]₄), or titanium tetraethoxide (Ti[OH(CH₂)₂]₄). The halogen solution C includes a fluorine-containing solution, a chlorine-containing solution, a bromine-containing solution, or an iodine-containing solution. The solvent D includes water, methanol, ethanol, or a mixed solvent thereof at any ratio. The ratio of water to methanol in the mixed solvent of water and methanol is, for example, but is not limited to, 3:1.

According to an embodiment, the method for preparing the spray solution includes adding the aluminium oxide precursor A, the titanium oxide precursor B and the halogen solution C to the solvent D to form a mixed solution. The concentration of the aluminium oxide precursor A in the mixed solution is from 0.01 M to 1 M, and exemplarily from 0.05 M to 0.2 M. The concentration of the titanium oxide precursor B in the mixed solution is from 0.01 M to 1 M, and exemplarily from 0.05 M to 0.2 M. The concentration of the halogen solution C in the mixed solution is from 0.01 M to 1 M, and exemplarily 0.1 M.

Then Step S20 is performed to stir and fully mix the mixed solution.

Next, Step S30 is performed, to spray the mixed solution onto the substrate to form an optical passivation film (S40). The substrate is, for example, a blank substrate, a solar cell element or other electronic elements. If the substrate is a blank substrate, an optical passivation film product is formed after the optical passivation film is formed on the substrate. If the substrate is a solar cell element, a solar cell element having the optical passivation film is formed after the optical passivation film is formed on the substrate.

Based on the aforesaid, in Step S30, the substrate 200 is disposed on a heating device 300, as shown in FIG. 3. In other words, the substrate 200 can have a specific temperature by heating with the heating device 300. Here, the temperature of the heating device 300 (i.e., the temperature at which the substrate 200 is heated) is from 300 to 600° C., and exemplarily from 350 to 450° C.

In addition, the method for spraying the mixed solution onto the substrate 200 is, for example, performing an ultrasonic atomization spraying process. In this embodiment, as shown in FIG. 3, the mixed solution 500 is ultrasonically atomized, and then the atomized mixed solution 500 is sprayed on the heated substrate 200 by a nozzle 400.

Based on the aforesaid, in this embodiment, the mixed solution is sprayed on the heated substrate 200 through an ultrasonic atomization spraying process. Therefore, once the mixed solution is sprayed on the heated substrate 200, a film is immediately formed. For example, an optical passivation film with a thickness of about 100 nm is formed in about 10 minutes after the ultrasonic atomization spraying process is performed. Therefore, the manufacturing of the optical passivation film can be finished with the ultrasonic atomization spraying process used in this embodiment in a short time. The optical passivation film formed by using the method above includes Ti₁₋ₓAlₓO_{y}:Z, where Z represents a halogen, x is from 0.05 to 0.95, and y is greater than 0.

According to another embodiment, after the optical passivation film is formed through the ultrasonic atomization spraying process, an annealing step may be further performed; however the disclosure is not limited thereto. The temperature of the annealing step is approximately 700° C. and the annealing time is about 1 hour.

### Embodiment 2

FIG. 4 is a schematic view of a method for manufacturing an optical passivation film according to an embodiment of the disclosure. Referring to FIG. 4, the method in this embodiment is the same as that in FIG. 3. Therefore, the same element is indicated with the same numeral, and is not repeatedly described herein. In the embodiment of FIG. 4, the method for preparing a spray solution includes mixing an aluminium oxide precursor and a solvent to prepare an aluminium oxide solution 510 and mixing a titanium oxide precursor and the solvent to prepare a titanium oxide solution 520. The aluminium oxide solution 510 or the titanium oxide solution 520 or both of them contain(s) a halogen solution.

In this embodiment, the aluminium oxide precursor in the aluminium oxide solution 510 includes an aluminium alkoxide (Al[OCH(CH₃)₂)]₃), aluminium chloride (AlCl₃), or aluminium nitrate. The titanium oxide precursor in the titanium oxide solution 520 includes titanium alkoxide (Ti[OCH(CH₃)₂]₄), or titanium tetraethoxide (Ti[OH(CH₂)₂]₄). The halogen solution includes a fluorine-containing solution, a chlorine-containing solution, a bromine-containing solution, or an iodine-containing solution. The solvent includes water, methanol, ethanol, or a mixed solvent thereof at any ratio. The ratio of water and methanol in the mixed solvent of water and methanol is, for example, but is not limited to, 3:1.

According to this embodiment, the concentration of the aluminium oxide precursor in the aluminium oxide solution 510 is about 0.1 M-0.2 M and the concentration of the titanium oxide precursor in the titanium oxide solution 520 is about 0.1 M-0.2 M. If the aluminium oxide solution 510 contains the halogen solution, the concentration of the halogen solution in the aluminium oxide solution 510 is about 0.1 M-0.2 M. If the titanium oxide solution 520 contains the halogen solution, the concentration of the halogen solution in the titanium oxide solution 520 is about 0.1 M -0.2 M.

Then, the aluminium oxide solution 510 containing the halogen and the titanium oxide solution 520 containing the halogen are respectively coated on the substrate 200 by using nozzles 410 and 420. Likewise, the substrate 200 is disposed on the heating device 300. Here, the temperature of the heating device 300 (i.e., the temperature at which the substrate 200 is heated) is from 300 to 600° C., and exemplarily from 350 to 450° C.

According to this embodiment, the method for spraying the aluminium oxide solution 510 containing the halogen and the titanium oxide solution 520 containing the halogen respectively on the substrate 200 is, for example, performing an ultrasonic atomization spraying process. Here, a condition for ultrasonic atomization includes atomizing the mixed solution into a micro-mist with a droplet size of 1-20 μm. Furthermore, a ratio of a spray volume of the aluminium oxide solution 510 to that of the titanium oxide solution 520 is 10:1-1:10, and exemplarily 1:1, so as to control an x value in the Ti₁₋ₓAlₓO_{y}:Z film

Based on the aforesaid, in this embodiment, the aluminium oxide solution 510 containing the halogen and the titanium oxide solution 520 containing the halogen are respectively atomized by using the ultrasonic atomization spraying process and then sprayed on the same heated substrate 200. Upon being sprayed on the heated substrate 200, the aluminium oxide solution 510 and the titanium oxide solution 520 is rapidly mixed and forms a film. For example, an optical passivation film with a thickness of about 100 nm is formed in about 10 minutes after the ultrasonic atomization spraying process is performed. Therefore, the manufacturing of the optical passivation film can be finished with the ultrasonic atomization spraying process used in this embodiment in a short time. The optical passivation film formed by using the method above includes Ti₁₋ₓAlₓO_{y}:Z, where Z represents a halogen, x is from 0.05 to 0.95, and y is greater than 0.

Based on the aforesaid, after the optical passivation film is formed through the ultrasonic atomization spraying process, an annealing step may be further performed; however the disclosure is not limited thereto. The temperature of the annealing step is approximately 700° C. and the annealing time is about 1 hour.

### EXAMPLES

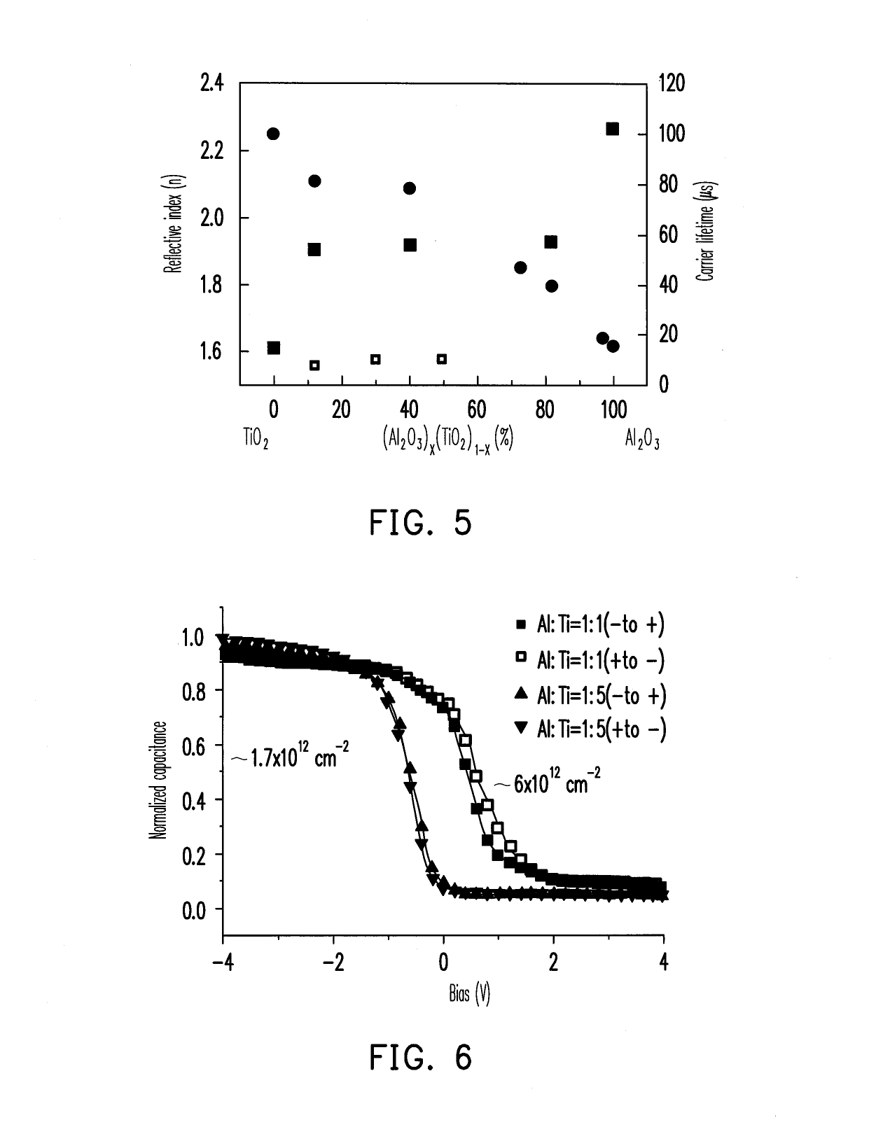

FIG. 5 is a graph showing a relation between a composition and a reflective index, and a carrier lifetime of an optical passivation film according to an embodiment of the disclosure. Referring to FIG. 5, the horizontal axis represents a component proportion of the optical passivation film (Ti₁₋ₓAlₓO_{y}) and the longitudinal axes represent the reflective index and the carrier lifetime. In addition, □ represents a relation between the component proportion and the carrier lifetime of an optical passivation film undoped with a halogen (Ti₁₋ₓAlₓO_{y}). ▪ represents a relation between the component proportion and the carrier lifetime of an optical passivation film doped with chlorine (Ti₁₋ₓAlₓO_{y}: Cl). represents a relation between the component proportion and the reflective index of an optical passivation film doped with chlorine (Ti₁₋ₓAlₓO_{y}: Cl). It can be known from FIG. 5 that the carrier lifetime of the optical passivation film undoped with a halogen (Ti₁₋ₓAlₓO_{y}) is relatively shorter than that of the optical passivation film doped with chlorine (Ti₁₋ₓAlₓO_{y}:Cl). Therefore, it indicates that the optical passivation film doped with a halogen atom has a better passivation effect.

It should be noted that because the optical passivation film (Ti₁₋ₓAlₓO_{y}:Z) provided in this embodiment is formed by preparing a spray solution and then performing an ultrasonic atomization spraying process, a user can easily control a proportion relation of titanium, aluminium and a halogen in the optical passivation film (Ti₁₋ₓAlₓO_{y}:Z) by adjusting the proportion of each component in the spray solution. It can be known from FIG. 5 that, with the difference of the proportion of titanium and aluminium in the optical passivation film (Ti₁₋ₓAlₓO_{y}:Z), the carrier lifetime and the reflective index performance of the optical passivation film (Ti₁₋ₓAlₓO_{y}:Z) may be different. Therefore, the user can adjust the proportion of each component in the optical passivation film (Ti₁₋ₓAlₓO_{y}:Z) according to the practical application of the optical passivation film.

FIG. 6 is a graph showing a relation between a bias and a normalized capacitance of an optical passivation film according to an embodiment of the disclosure. Referring to FIG. 6, the horizontal axis represents the bias and the longitudinal axis represents the standard capacitance value. In FIG. 6, the relation between a voltage and a capacitance of the optical passivation film (Ti₁₋ₓAlₓO_{y}:Z) with different proportions of aluminium and titanium is as shown by the curves in FIG. 6. It can be known from FIG. 6 that, when the optical passivation film (Ti₁₋ₓAlₓO_{y}) is undoped with a halogen, the voltage and capacitance behaviour is far lower that that of an optical passivation film doped with a halogen (for example, Ti₁₋ₓAlₓO_{y}:Cl).

Likewise, because the optical passivation film (Ti₁₋ₓAlₓO_{y}:Z) provided in this embodiment is formed by preparing a spray solution and then performing an ultrasonic atomization spraying process, a user can easily control a proportion relation of titanium, aluminium and a halogen in the optical passivation film (Ti₁₋ₓ,AlₓO_{y}:Z) by adjusting the proportion of each component in the spray solution. It can be known from FIG. 6 that, with the difference of the proportion of titanium and aluminium in the optical passivation film (Ti₁₋ₓAlₓO_{y}:Z), the voltage and capacitance behaviour of the optical passivation film (Ti₁₋ₓAlₓO_{y}:Z) may be different. Therefore, the user can adjust the proportion of each component in the optical passivation film (Ti₁₋ₓAlₓO_{y}:Z) according to the practical application of the optical passivation film.

One example and two comparative examples are listed in table 1, to demonstrate that the optical passivation film (Ti₁₋ₓAlₓO_{y}:Z) provided in the embodiment has a better passivation effect and adequate light capturing performance compared with a conventional anti-reflection coating.

TABLE 1

| | Comparative | Comparative | |
|---|---|---|---|
| Item | example 1 | example 2 | Example |
| Material | SiNₓ | Al₂O₃/TiO₂ | Ti₁₋ₓAlₓO_{y}: Z |
| Process | Chemical vapour | Spin coating | Spraying |
| | deposition (CVD) | | |
| Reflective index | 2.0-2.2 | 1.6-2.25 | 1.6-2.25 |
| Deposition rate | ~8 | 15 | 3-20 |
| (nm/min) | | | |
| Negative fix charge | +10-+30 | −5-−10 | −1-−60 |
| (10¹¹/cm) | | | |
| Electron-hole | ~3000 | ~300 | <100 |
| recombination rate | | | |
| (cm/s) | | | |

It can be known from table 1 that, a spraying method is adopted in the embodiment to fonn a film, so the deposition rate can be adjusted in a wide range. Furthermore, the values of the reflective index and the negative fix charge can both be adjusted in a wide range. Moreover, the electron-hole recombination rate of the optical passivation film provided in the embodiment is lower than that of the comparative example 1 and the comparative example 2.

In summary, the optical passivation film of the disclosure is formed by spraying the aluminium oxide solution and the titanium oxide solution onto the substrate. Therefore, the optical passivation film (Ti₁₋ₓAlₓO_{y}:Z) can be effectively adjusted to have an appropriate passivation effect and anti-reflection performance. The performance of a solar cell can be effectively increased by applying the optical passivation film onto the solar cell.

It will be apparent to those skilled in the art that various modifications and variations can be made to the structure of the disclosed embodiments without departing from the scope or spirit of the disclosure. In view of the foregoing, it is intended that the disclosure covers modifications and variations of this disclosure provided they fall within the scope of the following claims and their equivalents.

What is claimed is:

1. An optical passivation film, comprising Ti₁₋ₓAlₓO_{y}:Z, wherein Z represents a halogen, x is from 0.05 to 0.95, and y is greater than 0.

2. The optical passivation film according to claim 1, wherein Z represents fluorine, chlorine, bromine, or iodine.

3. The optical passivation film according to claim 1, wherein the halogen is present in the optical passivation film at an amount of at least 10¹⁸ atoms/cm³.

4. The optical passivation film according to claim 3, wherein the halogen is present in the optical passivation film at an amount of 10¹⁸-10²¹ atoms/cm³.

5. A method for manufacturing an optical passivation film, comprising:
preparing a spray solution, wherein the spray solution comprises an aluminium oxide precursor, a titanium oxide precursor, a halogen solution and a solvent;
disposing a substrate on a heating device to heat the substrate; and
spraying the spray solution onto the substrate to form an optical passivation film, wherein the optical passivation film comprises Ti₁₋ₓAlₓO_{y}:Z, wherein Z represents a halogen, x is from 0.05 to 0.95, and y is greater than 0.

6. The method for manufacturing an optical passivation film according to claim 5, wherein the aluminium oxide precursor comprises an aluminium alkoxide, aluminium chloride, or aluminium nitrate.

7. The method for manufacturing an optical passivation film according to claim 5, wherein the titanium oxide precursor comprises a titanium alkoxide, or titanium tetraethoxide.

8. The method for manufacturing an optical passivation film according to claim 5, wherein the solvent comprises water, methanol, ethanol, or a combination thereof.

9. The method for manufacturing an optical passivation film according to claim 5, wherein
the step of preparing the spray solution comprises mixing the aluminium oxide precursor, the titanium oxide precursor, the halogen solution and the solvent at the same time, to form a mixed solution; and
the step of spraying the spray solution onto the substrate comprises spraying the mixed solution onto the substrate by using a nozzle.

10. The method for manufacturing an optical passivation film according to claim 9, wherein the concentration of the aluminium oxide precursor in the mixed solution is from 0.01 M to 1 M, the concentration of the titanium oxide precursor in the mixed solution is from 0.01 M to 1 M, and the concentration of the halogen solution in the mixed solution is from 0.01 M to 1 M.

11. The method for manufacturing an optical passivation film according to claim 5, wherein
the step of preparing the spray solution comprises mixing the aluminium oxide precursor and the titanium oxide precursor respectively with the solvent, so as to prepare an aluminium oxide solution and a titanium oxide solution, wherein at least one of the aluminium oxide solution and the titanium oxide solution comprises the halogen solution; and
the step of spraying the spray solution onto the substrate comprises spraying the aluminium oxide solution and the titanium oxide solution respectively onto the substrate by using multiple nozzles.

12. The method for manufacturing an optical passivation film according to claim 11, wherein a ratio of the spray volume of the aluminium oxide precursor to that of the titanium oxide solution is from 10:1 to 1:10.

13. The method for manufacturing an optical passivation film according to claim 5, wherein the spraying process comprises an ultrasonic atomization spraying process.

14. The method for manufacturing an optical passivation film according to claim 5, wherein a temperature of the heating device is from 300 to 600° C.

15. The method for manufacturing an optical passivation film according to claim 5, further comprising an annealing step after the optical passivation film is formed.

16. A solar cell, comprising:
a semiconductor substrate;
an optical passivation film, disposed on the semiconductor substrate, wherein the optical passivation film comprises Ti₁₋ₓAlₓO_{y}:Z, wherein Z represents a halogen, x is from 0.05 to 0.95, and y is greater than 0; and
a first electrode and a second electrode, disposed respectively on two opposite surfaces of the semiconductor substrate.

17. The solar cell according to claim 16, wherein Z represents fluorine, chlorine, bromine, or iodine.

18. The solar cell according to claim 16, wherein the halogen is present in the optical passivation film at an amount of at least 10¹⁸ atoms/cm³.

19. The solar cell according to claim 18, wherein the halogen is present in the optical passivation film at an amount of 10¹⁸-10²¹ atoms/cm³.
